(19) United States
(12) Patent Application Publication
(10) Pub. No.: US 2024/0363430 A1
(43) Pub. Date: Oct. 31, 2024

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Chih-Yi Wang, Tainan City (TW); Wei-Che Chen, Kaohsiung City (TW); Hung-Chun Lee, Pingtung County (TW); Yun-Yang He, Changhua County (TW); Wei-Hao Chang, Taichung City (TW); Chang-Yih Chen, Tainan City (TW); Kun-Szu Tseng, Tainan City (TW); Yao-Jhan Wang, Tainan City (TW); Ying-Hsien Chen, Tainan City (TW)

(73) Assignee: UNITED MICROELECTRONICS CORP., Hsin-Chu City (TW)

(21) Appl. No.: 18/203,654

(22) Filed: May 31, 2023

(30) Foreign Application Priority Data
Apr. 27, 2023 (TW) 112115663

(51) Int. Cl. H01L 21/8234; H01L 27/088; H01L 29/06; H01L 29/66; H01L 29/78

(52) U.S. Cl. CPC H01L 21/823481; H01L 21/823431; H01L 27/0886; H01L 29/0607; H01L 29/66795; H01L 29/7851; H01L 29/66545

(57) ABSTRACT

A method for fabricating a semiconductor device includes the steps of first providing a substrate having an active region as the substrate includes a medium-voltage (MV) region and a low-voltage (LV) region, forming a first divot adjacent to one side of the active region, forming a second divot adjacent to another side of the active region, forming a first liner in the first divot and the second divot and on the substrate of the MV region and LV region, forming a second liner on the first liner, and then removing the second liner, the first liner, and the substrate on the LV region for forming a fin-shaped structure.

### BACKGROUND OF THE INVENTION

### 1. Field of the Invention

The invention relates to a method of fabricating semiconductor device, and more particularly to a method of integrating high-voltage (HV) device, medium-voltage (MV) device, and low-voltage (LV) device.

### 2. Description of the Prior Art

In current semiconductor processing, controllers, memories, circuits of low-voltage operation and power devices of high-voltage operation are largely integrated into a single chip to achieve a single-chip system. The power device, such as vertical double-diffusion metal-oxide-semiconductor (VDMOS), insulated gate bipolar transistor (IGBT) and lateral diffusion MOS (LDMOS), is employed to increase power switching efficiency and decrease the loss of energy resources. It is often required that the switching transistors withstand high breakdown voltages and operate at a low on-resistance.

Moreover with the trend in the industry being towards scaling down the size of the metal oxide semiconductor transistors (MOS), three-dimensional or non-planar transistor technology, such as fin field effect transistor technology (FinFET) has been developed to replace planar MOS transistors. Since the three-dimensional structure of a FinFET increases the overlapping area between the gate and the fin-shaped structure of the silicon substrate, the channel region can therefore be more effectively controlled. This way, the drain-induced barrier lowering (DIBL) effect and the short channel effect are reduced. The channel region is also longer for an equivalent gate length, thus the current between the source and the drain is increased. In addition, the threshold voltage of the fin FET can be controlled by adjusting the work function of the gate.

However as the scale of current devices continue to decrease the integration of high-voltage devices and FinFET devices start to face numerous challenges such as current leakage and control of breakdown voltage. Hence, how to improve the current fabrication for improving performance of the device has become an important task in this field.

### SUMMARY OF THE INVENTION

According to an embodiment of the present invention, a method for fabricating a semiconductor device includes the steps of first providing a substrate having an active region as the substrate includes a medium-voltage (MV) region and a low-voltage (LV) region, forming a first divot adjacent to one side of the active region, forming a second divot adjacent to another side of the active region, forming a first liner in the first divot and the second divot and on the substrate of the MV region and LV region, forming a second liner on the first liner, and then removing the second liner, the first liner, and the substrate on the LV region for forming a fin-shaped structure.

According to another aspect of the present invention, a semiconductor device includes a substrate having an active region, a first divot adjacent to one side of the active region, a second divot adjacent to another side of the active region, and a gate structure on the first active region.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-12 illustrate a method for fabricating a semiconductor device according to an embodiment of the present invention.

### DETAILED DESCRIPTION

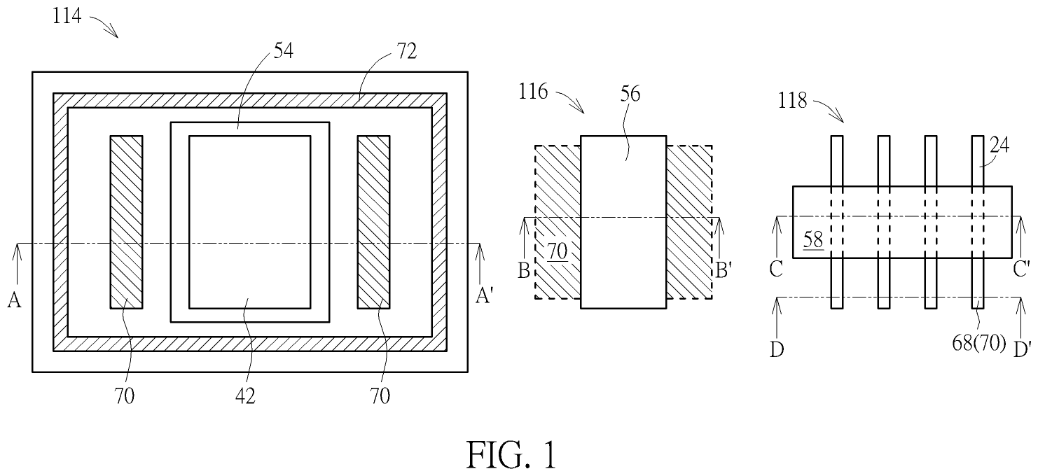

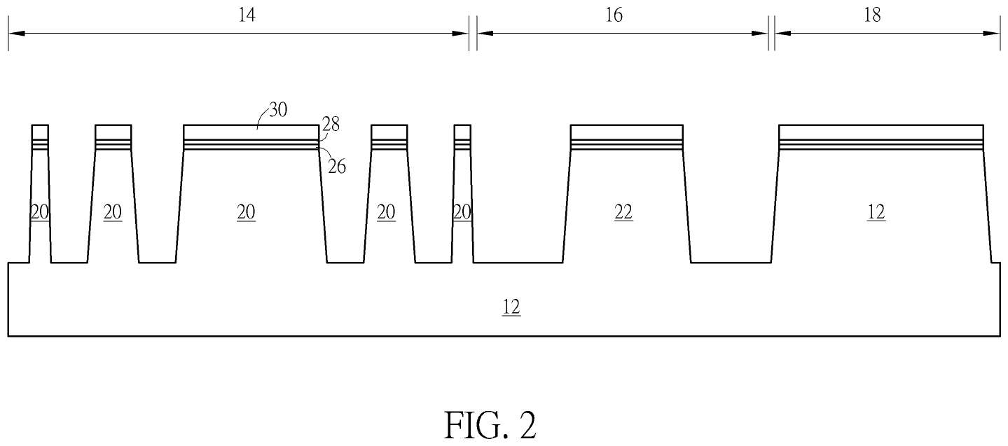

Referring to FIGS. 1-12, FIGS. 1-12 illustrate a method for fabricating a semiconductor device according to an embodiment of the present invention, in which FIG. 1 illustrates a top view for fabricating the semiconductor device according to an embodiment of the present invention and FIGS. 2-11 illustrate cross-section views for fabricating the semiconductor device along the sectional lines AA′, BB′, and CC′. As shown in FIGS. 1-2, a substrate 12 such as a silicon substrate or silicon-on-insulator (SOI) substrate is provided and three or more transistor regions including a high voltage (HV) region 14, a medium-voltage (MV) region 16, and a low-voltage (LV) region 18 are defined on the substrate 12, in which at least a HV device 114 is disposed on the HV region 14, a MV device 116 is disposed on the MV region 16, the LV region 18 could further include a core region and/or an input/output (I/O) region, and a LV device 118 is disposed on the LV region 18. Preferably, FIGS. 2-11 are cross-section views illustrating a method for fabricating the semiconductor device taken along the sectional line AA′ of the HV region 14, the sectional line BB′ of the MV region 16, and the sectional line CC′ of the LV region 18.

In this embodiment, the three regions 14, 16, 18 could be transistor regions having same conductive type or different conductive types. For instance, each of the three regions 14, 16, 18 could be a PMOS region or a NMOS region and the three regions 14, 16, 18 are defined to fabricate gate structures having different threshold voltages in the later process. Preferably, it would be desirable to first conduct an implantation process to form p-type deep wells on the HV region 14 and MV region 16 and a n-type deep well on the LV region 18, but not limited thereto.

Next, a liner 26, a liner 28, and a hard mask 30 could be formed on the substrate 12 of the HV region 14, the MV region 16, and the LV region 18, in which the liner 26 preferably includes silicon oxide (SiO₂), the liner 28 includes silicon nitride (SiN), and the hard mask 30 includes silicon oxide (SiO₂), but not limited thereto. Next, a photo-etching process is conducted to remove part of the hard mask 30, part of the liner 28, part of the liner 26, and part of the substrate 12 on the HV region and MV region 16 to form a plurality of openings and at the same time defining a plurality of bases 20 on the HV region 14 and also a plurality of bases 22 on the MV region 16. It should be noted that the substrate 12 on the LV region 18 has not been patterned to form fin-shaped structures at this stage.

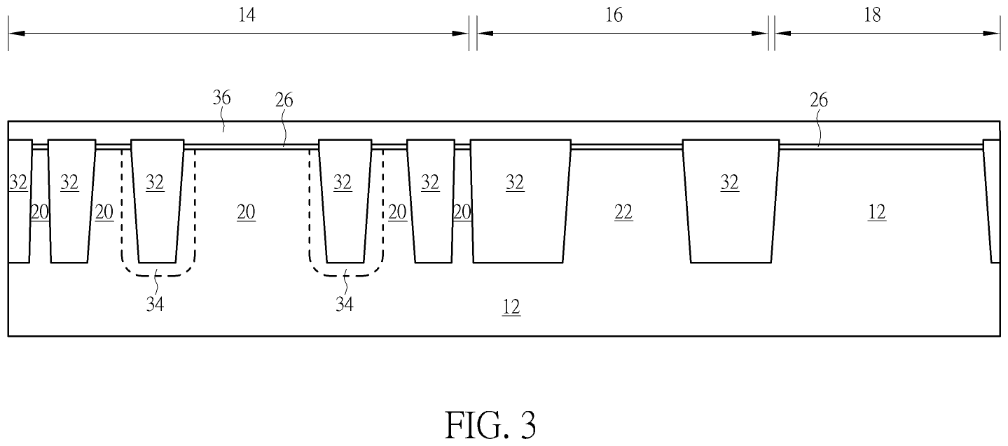

Next, as shown in FIG. 3, a flowable chemical vapor deposition (FCVD) process is conducted to form an insulating layer 32 made of silicon oxide on the bases 20, 22 and filling the openings between the bases 20, 22, and a planarizing process such as chemical mechanical polishing (CMP) process is conducted to remove the hard mask 30 so that the top surfaces of the liner 28 and the insulating layer 32 are coplanar.

Next, the liner 28 made of silicon oxide is removed through etching process to expose the liner 26 made of silicon nitride underneath. As a result, the top surface of the insulating layer 32 becomes slightly higher than the top surface of the liner 26 and at the same time forming recesses (not shown) directly above the liner 26. Next, an ion implantation process is conducted to form doped regions 34 in the base 20 on the HV region 14, in which the doped regions 34 preferably serve as lightly doped drains (LDDs) for the HV device 114 formed afterwards. Next, a hard mask 36 is formed on the bases 20, 22 and the substrate 12 on the HV region 14, the MV region 16, and the LV region 18 and filling the recesses above the liner 26. In this embodiment, the hard mask 36 is preferably made of SiN, but not limited thereto.

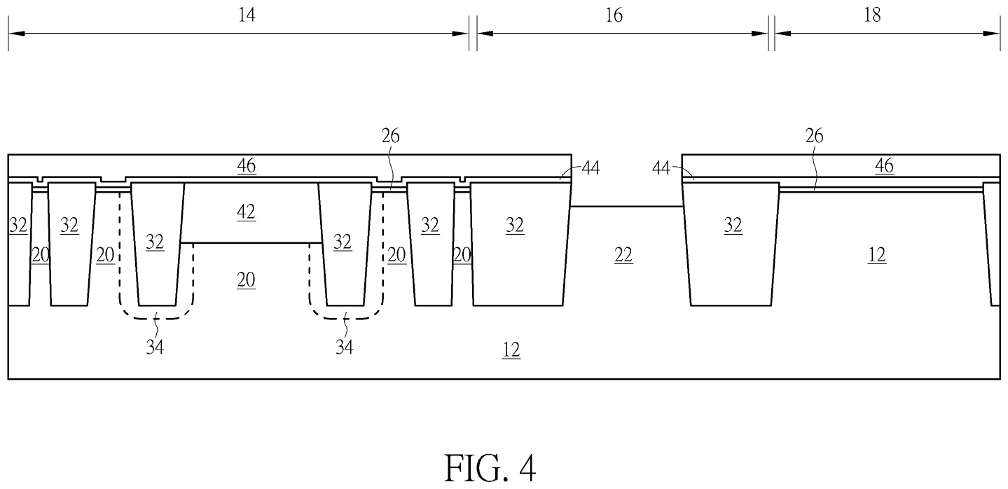

Next, as shown in FIG. 4, a patterned mask such as a patterned resist is formed on the hard mask 36 on the MV region 16 and the LV region 18 as the patterned mask includes an opening exposing the surface of the hard mask 36 on the HV region 14. Next, an etching process is conducted by using the patterned mask as mask to remove part of the hard mask 36 and part of the base 20 for forming a trench.

Next, after removing the patterned mask, an oxide growth process or more specifically a rapid thermal oxidation (RTO) process is conducted to form a gate dielectric layer 42 made of silicon oxide on the base 20 on the HV region 14, and the hard mask 36 is completely removed thereafter. Preferably, the top surface of the gate dielectric layer 42 is even with the top surface of the insulating layer 32 on both MV region 16 and LV region 18.

Next, another patterned mask (not shown) such as a patterned resist could be formed to cover the insulating layer 32 on the HV region 14 and MV region 16 as the patterned mask includes an opening exposing the top surface of the liner 26 and insulating layer 32 on the LV region 18, and then an ion implantation process is conducted to implant dopants into the substrate 12 on the LV region 18 for adjusting threshold voltage (Vt) of the device. The patterned mask is then removed thereafter.

Next, a hard mask 44 made of SiN is formed on the HV region 14, the MV region 16, and the LV region 18 including the gate dielectric layer 42 on the HV region 14, the base 22 on the MV region 16, and the substrate 12 on the LV region 18, and then another patterned mask 46 such as a patterned resist is formed on the insulating layer 32 on the HV region 14 and LV region 18, in which the patterned mask 46 includes an opening exposing the hard mask 44 on the MV region 16. Next, an etching process is conducted by using the patterned mask 46 as mask to remove the hard mask 44, part of the insulating layer 32, the liner 26, and even part of the base 22 on the MV region 16 for exposing the surface of the base 22.

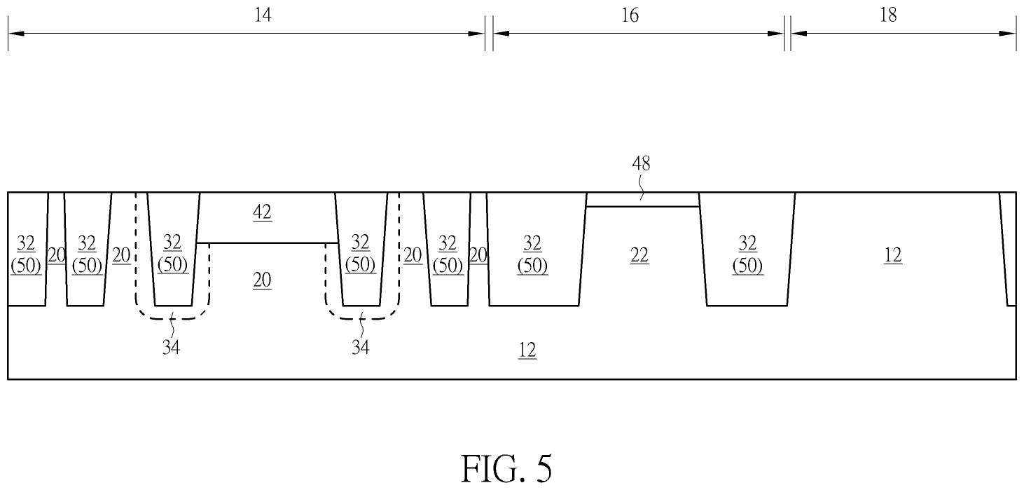

Next, as shown in FIG. 5, another oxide growth process such as a RTO process is conducted to form a gate dielectric layer 48 made of silicon oxide on the base 22 on MV region 16, in which the top surface of the gate dielectric layer 48 on the MV region 16 could be even with the top surface of the gate dielectric layer 42 on the HV region 14 while the thickness of the gate dielectric layer 42 on the HV region 14 is greater than the thickness of the gate dielectric layer 48 on the MV region 16. In this embodiment, the thickness of the gate dielectric layer 42 on the HV region 14 could be more than one time such as 1.5 times or even two times the thickness of the gate dielectric layer 48 on the MV region 16.

Next, the patterned mask 46 and remaining hard mask 44 on the HV region 14, MV region 16, and LV region 18 are removed, and an etching process is conducted to completely remove the liner 26 on the LV region 14 for exposing the top surface of the substrate 12 and also remove part of the insulating layer 32 on the HV region 14, MV region 16, and LV region 18 so that the top surface of the insulating layer 32 is even with the top surface of the bases 20, 22 and the substrate 12 for forming a shallow trench isolation (STI) 50. It should be noted that at this stage, the top surface of the gate dielectric layer 42 on the HV region 14 is substantially even with the top surface of the gate dielectric layer 48 on the MV region 16 and the top surface of the substrate 12 on the LV region 18.

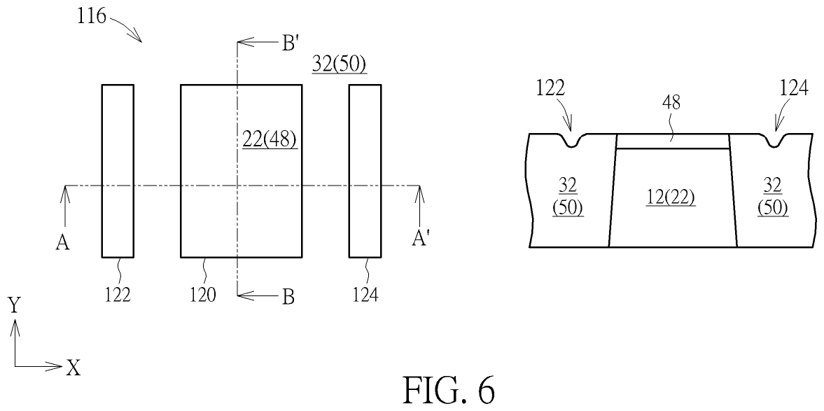

Referring to FIG. 6, FIG. 6 illustrates a structural view of the semiconductor device on the MV region 16 after removing the hard mask 44 made of silicon nitride, in which the left portion of FIG. 6 illustrates a top view of the MV device 116 on the MV region 16, the right portion of FIG. 6 illustrates a cross-section of the left portion taken along the sectional line AA′, and the MV region 16 of FIG. 5 is in fact a cross-section of the left portion of FIG. 6 taken along the sectional line BB′. As shown in FIG. 6, the MV device 116 includes an active region 120 disposed on the substrate 12, in which the active region 120 is extending alone the Y-direction on the substrate 12. It should be noted that after the hard mask 44 is removed, two divots 122, 124 are formed on the STI 50 adjacent to two sides of the active region 120. Preferably, the divots 122, 124 if viewed under a top view perspective are also extending along the Y-direction adjacent to two sides of the active region 120. As shown from the cross-section perspective on the right portion of FIG. 6, the depth of the divots 122, 124 preferably not surpassing the bottom surface of the gate dielectric layer 48. For instance, the bottom surface of the divots 122, 124 could be even with or slightly higher than the bottom surface of the gate dielectric layer 48. According to an embodiment of the present invention, the depth of the divots 122, 124 is preferably less than the thickness of the gate dielectric layer 48 or more specifically less than half the thickness of the gate dielectric layer 48. For instance, the depth of the divots 122, 124 is preferably between 50-100 Angstroms while the thickness of the gate dielectric layer 48 is approximately 210 Angstroms.

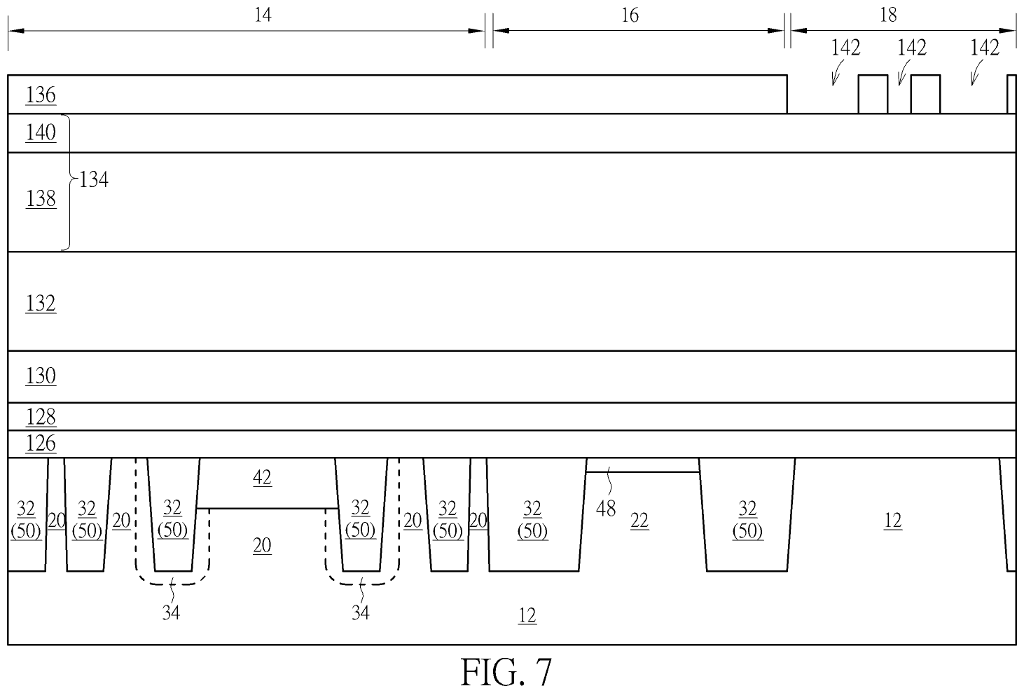

Next, as shown in FIG. 7, a liner 126 is formed on the substrate 12 of the HV region 14, MV region 16, and LV region 18, another liner 128 is formed on the liner 126, a hard mask 130 is formed on the liner 128, a silicon layer 132 is formed on the hard mask 130, another hard mask 134 is formed on the silicon layer 132, and a patterned mask 136 is formed on the hard mask 134, in which the patterned mask 136 includes a plurality of openings 142 exposing the surface of the hard mask 134 on the LV region 18. In this embodiment, the liner 126 preferably includes silicon oxide and the thickness thereof is between 38-42 Angstroms or most preferably 40 Angstroms, the liner 128 includes silicon nitride and the thickness thereof is between 175-215 Angstroms or most preferably 200 Angstroms, the hard mask 130 includes silicon oxide and the thickness thereof is between 530-560 Angstroms or most preferably 545 Angstroms, and the silicon layer 132 includes amorphous silicon and the thickness thereof is between 1100-1200 Angstroms or most preferably 1150 Angstroms.

Moreover, the hard mask 134 preferably includes a composite hard mask which could further include an organic dielectric layer (ODL) 138 and a silicon-containing hard mask bottom anti-reflective coating (SHB) 140, in which the thickness of the ODL 138 is approximately 1440 Angstroms and the thickness of the SHB 140 is 400 Angstroms. The patterned mask 136 preferably includes patterned resist and the thickness thereof is 750 Angstroms, but not limited thereto. It should be noted that since the liners 126 and 128 are disposed on the surface of the substrate 12 on the HV region 14, the MV region 16, and the LV region 18 entirely at this stage, the liners 126 and 128 are also disposed to fully fill the aforementioned divots 122, 124 adjacent to two sides of the active region 120 on the MV region 16.

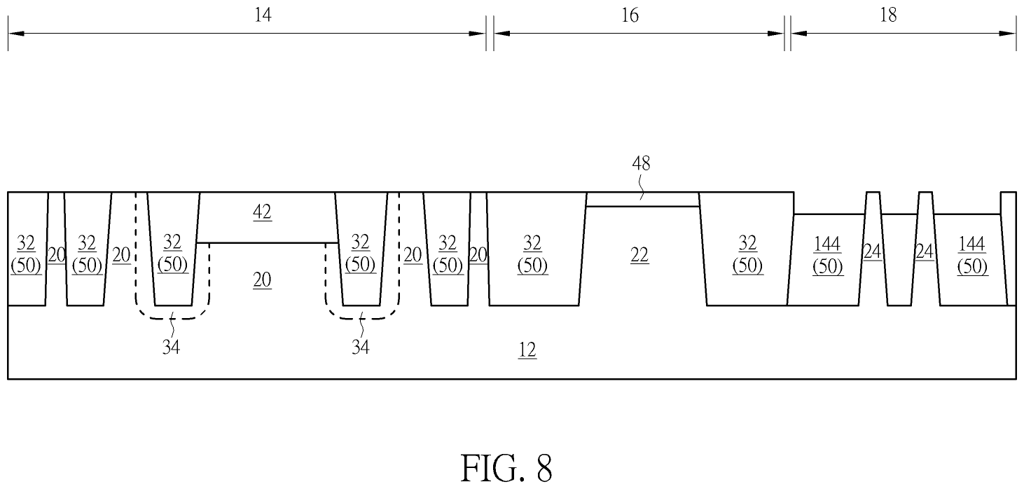

Next, as shown in FIG. 8, one or more etching process is conducted by using the patterned mask 136 as mask to remove part of the hard mask 134, part of the silicon layer 132, part of the hard mask 130, part of the liners 128, 126, and part of the substrate 12 to form a plurality of fin-shaped structures 24 and trenches between the LV region 18 and the MV region 16. After removing the hard mask 134 and the silicon layer 132, a fin remove and/or fin cut process could be selective conducted to remove part of the fin-shaped structures 24, an atomic layer deposition (ALD) process is conducted to form a liner (not shown) on the surface of the hard mask 130 on the HV region 14 and MV region 16 and fill into the trenches on the LV region 18, and a flowable chemical vapor deposition (FCVD) process is conducted to form a dielectric layer 144 on the liner to fully fill the trenches on the LV region 18. Next, a planarizing process such as a CMP process is conducted to remove part of the dielectric layer 144 and all of the hard mask 130 and the liners 124, 126 to form a STI 50 in the trenches on the LV region 18. Next, another etching process could be conducted to remove part of the STI 50 on the LV region 18 so that the top surface of the STI 50 becomes slightly lower than the top surface of the fin-shaped structures 24. In this embodiment, the liner 126 and the dielectric layer 144 are preferably made of same material such as silicon oxide.

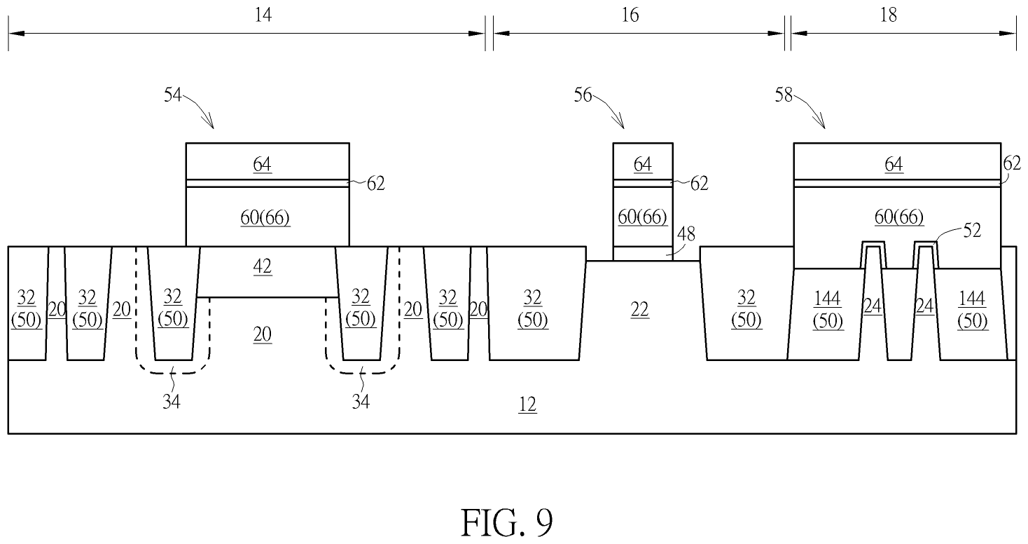

Next, as shown in FIG. 9, an oxidation process such as an in-situ steam generation (ISSG) process is conducted to form a gate dielectric layer 52 on the surface of fin-shaped structures 24 on the LV region 18. Next, gate structures 54, 56, 58 or dummy gates could be formed on the bases 20, 22 and the fin-shaped structures 24 on the HV region 14, MV region 16, and LV region 18. In this embodiment, the formation of the gate structures 54, 56, 58 could be accomplished by a gate first process, a high-k first approach from gate last process, or a high-k last approach from gate last process. Since this embodiment pertains to a high-k last approach, a gate material layer 60 preferably made of polysilicon, a hard mask 62 made of SiN, and a hard mask 64 made of silicon oxide could be formed sequentially on the gate dielectric layers 42, 48, 52, and a pattern transfer process is then conducted by using a patterned resist (not shown) as mask to remove part of the hard masks 62, 64 and part of the gate material layer 60 through single or multiple etching processes. After stripping the patterned resist, gate structures 54, 56, 58 composed of gate dielectric layers 42, 48, 52 respectively and patterned gate material layers 60 are formed on the substrate 12 on each region, in which the patterned gate material layer 60 becomes a gate electrode 66 on each region.

Next, at least a spacer (not shown) is formed on sidewalls of the gate structures 54, 56, 58. In this embodiment, the spacer could be a single spacer or a composite spacer, in which the spacer could further include an offset spacer (not shown) and a main spacer (not shown). The offset spacer and the main spacer are preferably made of different materials while the offset spacer and main spacer could all be selected from the group consisting of SiO₂, SiN, SiON, and SiCN, but not limited thereto.

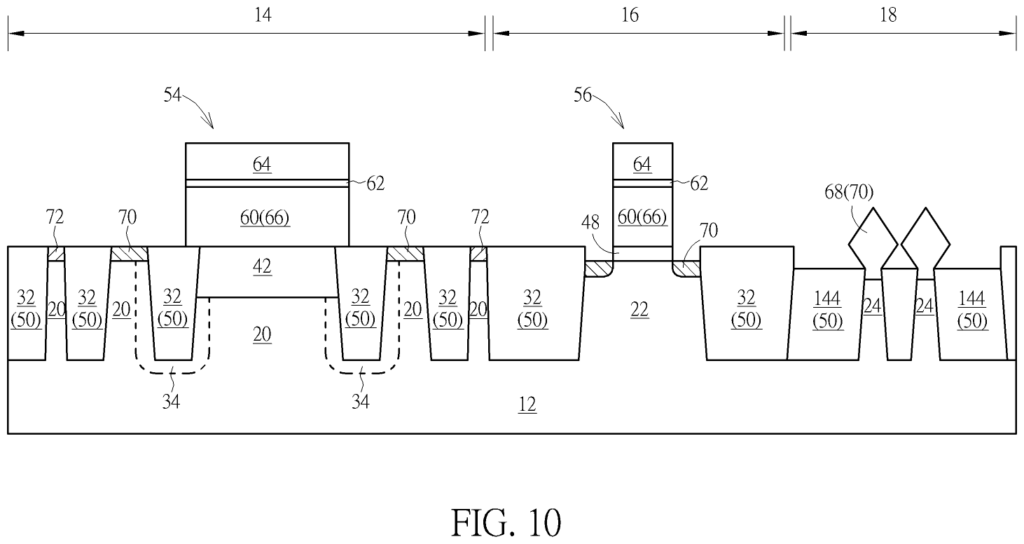

Referring to FIG. 10, FIG. 10 illustrates a method for fabricating a semiconductor device according to an embodiment of the present invention taken along the sectional line AA′ of the HV region 14, the sectional line BB′ of the MV region 16, and the sectional line DD′ of the LV region 18. As shown in FIG. 10, one or more dry etching and/or wet etching process could be conducted by using the gate structure 58 and spacer on the LV region 18 as mask to remove part of the substrate 12 for forming recesses (not shown) adjacent to two sides of the gate structure 58. Next, a selective epitaxial growth (SEG) process is conducted to form epitaxial layers 68 in the recesses.

As shown in the cross-section view of FIG. 10, the epitaxial layers 68 on the LV region 18 also share substantially same cross-section shape with the recesses. For instance, the cross-section of each of the epitaxial layers 68 could also include a circle, a hexagon, or an octagon depending on the demand of the product. In this embodiment, the epitaxial layers 68 could also be formed to include different materials depending on the type of transistor being fabricated. For instance, if the MOS transistor being fabricated were to be a PMOS transistor, the epitaxial layers 68 could be made of material including but not limited to for example SiGe, SiGeB, or SiGeSn. If the MOS transistor being fabricated were to be a NMOS transistor, the epitaxial layers 68 could be made of material including but not limited to for example SiC, SiCP, or SiP. Moreover, the SEG process could also be adjusted to form a single-layered epitaxial structure or multi-layered epitaxial structure, in which heteroatom such as germanium atom or carbon atom of the structure could be formed to have gradient while the surface of the epitaxial layers 68 is preferred to have less or no germanium atom at all to facilitate the formation of silicide afterwards.

Next, a photo-etching process could be conducted to remove part of the gate dielectric layer 48 on the MV region 16 for exposing the surface of the base 22 adjacent to two sides of the gate structure 56, and then one or more ion implantation process is conducted to form source/drain regions 70 in the bases 20, 22 adjacent to two sides of the gate structures 54, 56 on the HV region 14 and MV region 16 and at the same time form doped regions serving as an electrostatic discharge (ESD) protection ring 72 in the base 20 around the HV device 114 on the HV region 14. Preferably, the source/drain regions 70 and the ESD protection ring 72 on the HV region 14 include dopants of different conductive type. For instance, either one of the source/drain regions 70 and the ESD protection ring 72 could include n-type dopants while the other include p-type dopants.

According to an embodiment of the present invention, it would also be desirable to form source/drain regions 70 in part or all of the epitaxial layers 68 on the LV region 18. According to another embodiment of the present invention, the source/drain regions 70 could also be formed insituly during the SEG process. For instance, the source/drain regions 70 could be formed by implanting p-type dopants during formation of a SiGe epitaxial layer, a SiGeB epitaxial layer, or a SiGeSn epitaxial layer for PMOS transistor, or could be formed by implanting n-type dopants during formation of a SiC epitaxial layer, SiCP epitaxial layer, or SiP epitaxial layer for NMOS transistor. By doing so, it would be desirable to eliminate the need for conducting an extra ion implantation process for forming the source/drain regions 70. Moreover, the dopants within the source/drain regions 70 could also be formed with a gradient, which is also within the scope of the present invention.

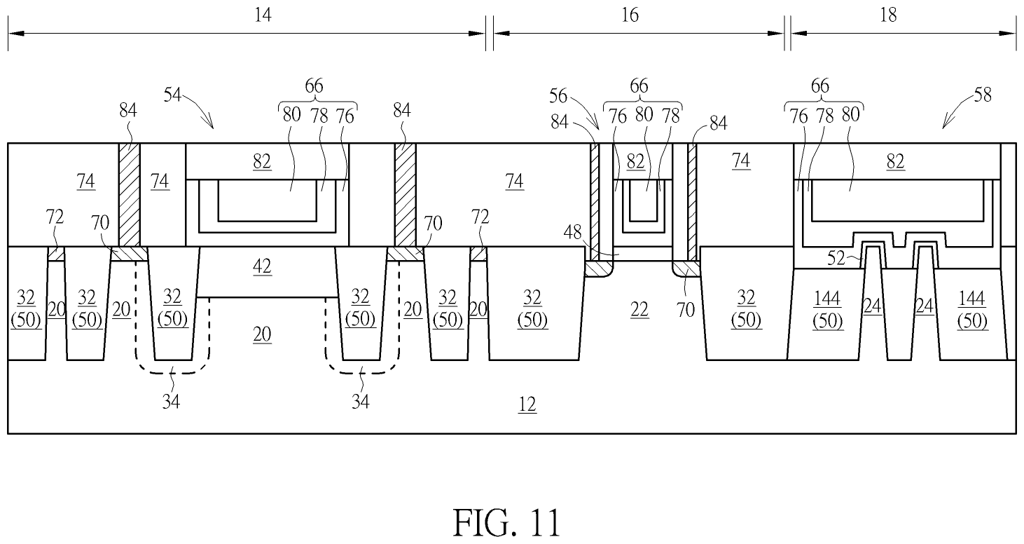

Next, as shown in FIG. 11, a selective contact etch stop layer (CESL) (not shown) could be formed on the substrate 12 surface to cover the gate structures 54, 56, 58 on the HV region 14, MV region 16, and LV region 18, and an interlayer dielectric (ILD) layer 74 is formed on the CESL afterwards. Next, a planarizing process such as a chemical mechanical polishing (CMP) process is conducted to remove part of the ILD layer 74 and part of the CESL so that the top surfaces of the hard mask 64 and ILD layer 74 are coplanar.

Next, a replacement metal gate (RMG) process is conducted to transform the gate structures 54, 56, 58 on the HV region 14, MV region 16, and LV region 18 into metal gates. For instance, the RMG process could be accomplished by first performing a selective dry etching or wet etching process using etchants including but not limited to for example ammonium hydroxide (NH₄OH) or tetramethylammonium hydroxide (TMAH) to remove the hard masks 62, 64 and the gate material layers 60 from gate structures 54, 56, 58 for forming recesses (not shown) in the ILD layer 74. Next, a high-k dielectric layer 76, a work function metal layer 78, and a low resistance metal layer 80 are formed in the recesses, and a planarizing process such as CMP is conducted to remove part of low resistance metal layer 80, part of work function metal layer 78, and part of high-k dielectric layer 76 to form metal gates. Preferably, the high-k dielectric layer 76, the work function metal layer 78, and the low resistance metal layer 80 altogether constitute the gate electrode 66 of each of the transistors or devices.

In this embodiment, the high-k dielectric layer 76 is preferably selected from dielectric materials having dielectric constant (k value) larger than 4. For instance, the high-k dielectric layer 46 may be selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT), lead zirconate titanate (PbZrₓTi₁₋ₓO₃, PZT), barium strontium titanate (BaₓSr₁₋ₓTiO₃, BST) or a combination thereof.

In this embodiment, the work function metal layer 78 is formed for tuning the work function of the metal gate in accordance with the conductivity of the device. For an NMOS transistor, the work function metal layer 78 having a work function ranging between 3.9 eV and 4.3 eV may include titanium aluminide (TiAl), zirconium aluminide (ZrAl), tungsten aluminide (WAl), tantalum aluminide (TaAl), hafnium aluminide (HfAl), or titanium aluminum carbide (TiAlC), but it is not limited thereto. For a PMOS transistor, the work function metal layer 78 having a work function ranging between 4.8 eV and 5.2 eV may include titanium nitride (TiN), tantalum nitride (TaN), tantalum carbide (TaC), but it is not limited thereto. An optional barrier layer (not shown) could be formed between the work function metal layer 78 and the low resistance metal layer 50 may include titanium (Ti), titanium nitride (TiN), tantalum (Ta) or tantalum nitride (TaN). Furthermore, the material of the low-resistance metal layer 80 may include copper (Cu), aluminum (Al), titanium aluminum (TiAl), cobalt tungsten phosphide (CoWP) or any combination thereof. Since the transformation of dummy gates into metal gates through RMG process is well known to those skilled in the art, the details of which are not explained herein for the sake of brevity. Next, part of the high-k dielectric layer 76, part of the work function metal layer 78, and part of the low resistance metal layer 80 are removed to form recesses (not shown), and a hard mask 82 is formed into each of the recesses so that the top surfaces of the hard masks 82 and the ILD layer 74 are coplanar. Preferably the hard masks 82 could include SiO₂, SiN, SiON, SiCN, or combination thereof.

Next, a photo-etching process is conducted by using a patterned mask (not shown) as mask to remove part of the ILD layer 74 and part of the CESL adjacent to the gate structures 54, 56, 58 for forming contact holes (not shown) exposing the source/drain regions 70 underneath. Next, conductive materials including a barrier layer selected from the group consisting of titanium (Ti), titanium nitride (TiN), tantalum (Ta), and tantalum nitride (TaN) and a metal layer selected from the group consisting of tungsten (W), copper (Cu), aluminum (Al), titanium aluminide (TiAl), and cobalt tungsten phosphide (CoWP) are deposited into the contact holes, and a planarizing process such as CMP is conducted to remove part of aforementioned barrier layer and low resistance metal layer for forming contact plugs 84 electrically connecting the source/drain regions 70. This completes the fabrication of a semiconductor device according to an embodiment of the present invention.

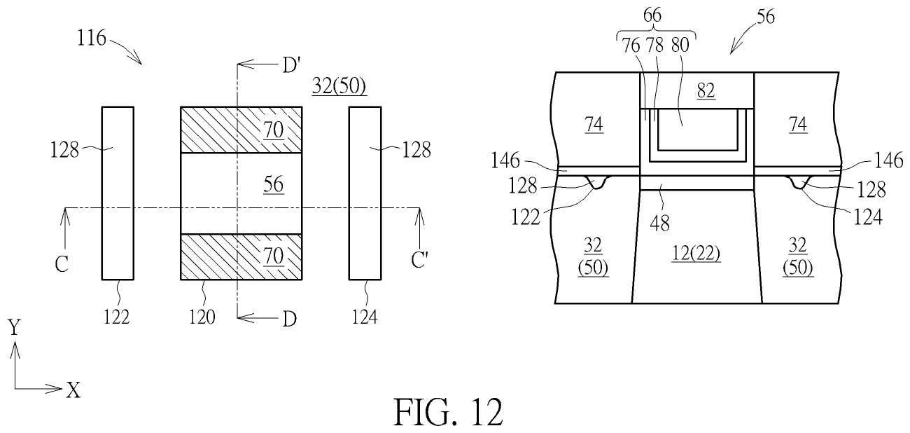

Referring to FIG. 12, FIG. 12 illustrates a structural view of the MV device 116 on the MV region 16 obtained after the fabrication process conducted in FIG. 11, in which the left portion of FIG. 12 illustrates a top view of the device on the MV region 16, the right portion of FIG. 12 illustrates a cross-section view of the left portion taken along the sectional line CC′, and the device on the MV region 16 shown in FIG. 11 is in fact a cross-section view of the left portion of FIG. 12 taken along the sectional line DD′. As shown in FIG. 12, the MV device 116 preferably includes an active region 120 disposed on the substrate 12, in which the active region 120 is extending along the Y-direction on the substrate 12. Viewing from the CC′ direction, the two divots 122, 124 are also extending along the Y-direction in the STI 50 adjacent to two sides of the active region 120, in which the divots 122, 124 are filled with a liner 128 made of silicon nitride. Viewing from the DD′ direction, a gate structure 56 is disposed on the substrate 12 and source/drain regions 70 are disposed in the substrate 12 adjacent to two sides of the gate structure 56.

As shown on the right portion, the top surface of the liner 128 filled into the divots 122, 124 could be slightly lower than or even with the top surface of the STI 50 or substrate 12 adjacent to the divots 122, 124. Even though the top surface of the liner 128 in this embodiment is even with the top surface of the gate dielectric layer 48, according to other embodiment of the present invention, the top surface of the liner 128 filled within the divots 122, 124 could also be slightly higher than the top surface of the substrate 12 directly under the gate structure 56 but lower than the top surface of the gate dielectric layer 48, which is also within the scope of the present invention.

Preferably, the depth of each of the divots 122, 124 or the thickness of the liner 128 is less than the thickness of the gate dielectric layer 48. According to an embodiment of the present invention, the depth of each of the divots 122, 124 or the thickness of the liner 128 is preferably less than half the thickness of the gate dielectric layer 48. For instance, the depth of the divots 122, 124 or the thickness of the liner 128 is between 50-100 Angstroms while the thickness of the gate dielectric layer 48 is about 210 Angstroms. Moreover, a dielectric layer or liner 146 made of silicon oxide or silicon nitride could be selectively disposed directly on the surface of the liner 128 and the surface of the STI 50, in which the liner 146 could be made from remaining liner 126 or gate dielectric layer 48 from the aforementioned process and the liner 146 and the ILD layer 74 directly above could be made of same or different material. If no liner 146 were disposed directly on top of the liner 128 in the divots 122, 124, the liner 128 within the divots 122, 124 would be contacting the ILD layer 74 directly, which are all within the scope of the present invention.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a semiconductor device, comprising:
providing a substrate comprising a first active region;
forming a first divot adjacent to one side of the first active region;
forming a second divot adjacent to another side of the first active region; and
forming a gate structure on the first active region.

2. The method of claim 1, wherein the substrate comprises a medium-voltage (MV) region and a low-voltage (LV) region, the method comprising:
forming the first active region on the MV region and a second active region on the LV region;
forming a first liner in the first divot and the second divot and on the substrate of the MV region;
forming a second liner on the first liner;
removing the second liner, the first liner, and the substrate on the LV region to form a fin-shaped structure and a trench between the MV region and the LV region;
forming a dielectric layer in the trench; and
planarizing the dielectric layer and the second liner to form a shallow trench isolation (STI).

3. The method of claim 2, wherein the first liner and the second liner comprise different materials.

4. The method of claim 2, wherein the second liner and the dielectric layer comprise same material.

5. The method of claim 2, wherein the first liner comprises silicon nitride.

6. The method of claim 2, wherein the second liner comprises silicon oxide.

7. The method of claim 2, wherein the first active region is extending along a first direction on the substrate.

8. The method of claim 7, wherein the first divot is extending along the first direction adjacent to one side of the first active region in a top view.

9. The method of claim 7, wherein the second divot is extending along the first direction adjacent to another side of the first active region in a top view.

10. A semiconductor device, comprising:
a substrate comprising an active region;
a first divot adjacent to one side of the active region;
a second divot adjacent to another side of the active region; and
a gate structure on the first active region.

11. The semiconductor device of claim 10, wherein the substrate comprises a medium-voltage (MV) region and a low-voltage (LV) region, the semiconductor device comprising:
the first active region on the MV region and a second active region on the LV region;
a shallow trench isolation (STI) between the first active region and the second active region;
a liner in the first divot and the second divot; and
a dielectric layer on the liner and the substrate.

12. The semiconductor device of claim 11, wherein the liner and the dielectric layer comprise different materials.

13. The semiconductor device of claim 11, wherein the liner comprises silicon nitride.

14. The semiconductor device of claim 11, wherein the dielectric layer comprises silicon oxide.

15. The semiconductor device of claim 10, wherein the first active region is extending along a first direction on the substrate.

16. The semiconductor device of claim 15, wherein the first divot is extending along the first direction adjacent to one side of the first active region in a top view.

17. The semiconductor device of claim 15, wherein the second divot is extending along the first direction adjacent to another side of the first active region in a top view.
